(19) United States
(12) Patent Application Publication
(10) Pub. No.: US 2012/0224238 A1
(43) Pub. Date: Sep. 6, 2012

(54) SUBSTRATE FASTENING STRUCTURE, OPTICAL SCANNING DEVICE, AND IMAGE FORMING APPARATUS

(76) Inventors: Nobuhiro Shirai, Osaka (JP); Ayumu Oda, Osaka (JP)

(21) Appl. No.: 13/398,338

(22) Filed: Feb. 16, 2012

(30) Foreign Application Priority Data
Mar. 3, 2011 (JP) 2011-046752

(51) Int. Cl. G02B 26/10; H05K 7/02

(52) U.S. Cl. 359/198.1; 361/759

(57) ABSTRACT

A substrate fastening structure is provided with a substrate on which an optical detection sensor is mounted, and a casing to which the substrate is secured internally. The casing is provided with a reference portion having a reference groove formed in a perpendicular direction with respect to a first surface configured on an inner side of the casing, and an opposing portion having an opposing groove that opposes the reference groove. The opposing portion is provided with a pass-through hole that is located on an extension of a straight line on which the reference groove and the opposing groove oppose each other, and that passes through the opposing portion. The substrate is inserted extending across the reference groove and the opposing groove, and has an opposing end face that opposes the opposing portion, and has a cut⁻out portion formed in the opposing end face, and a fastening member that is inserted into the pass-through hole presses the cut-out portion.

### CROSS-REFERENCE TO RELATED APPLICATION

This application claims priority under 35 U.S.C. §119(a) on Patent Application No. 2011-046752 filed in Japan on Mar. 3, 2011, the entire contents of which are herein by incorporated by reference.

### BACKGROUND OF THE INVENTION

1. Field of the Invention

The present invention relates to substrate fastening structures provided with a casing to which a substrate is secured internally, and to optical scanning devices provided with a substrate fastening structure, and also to image forming apparatuses provided with an optical scanning device.

2. Description of the Related Art

Conventionally, various forms have been conceived as structures where a substrate or a mirror or the like is secured to a casing. As a structure which secures a substrate parallel to the surface of the casing, mounting structures have been conceived (for example, see JP 2006-324269A) in which a hole portion is provided in the substrate, and a claw portion that is provided protruding from the casing inserts into the hole portion to latch onto the substrate. Furthermore, other structures have been conceived (for example, see JP 2009-179803A) in which a screw is inserted into a hole portion of the substrate to secure the substrate to the casing. As a structure in which the mirror is secured to the surface of the casing to stand perpendicular with respect to the surface of the casing, methods have been conceived (for example, see JP 2001-183573A) in which the position of the mirror is regulated by a support portion that extends perpendicularly from the surface of the casing, and a plate spring is inserted between the support portion and the mirror to secure the mirror to the surface of the casing.

However, with the structure described in JP 2006-324269A, it is necessary to form a large hole portion so that the claw portion can be inserted into the hole portion, and there is a risk that the mounting position accuracy of the substrate will be reduced due to differences in the sizes of the claw portion and the hole portion. Similarly, with the structure described in JP 2009-179803A, since the hole portion must be formed larger than the screw, there is a problem in the mounting position accuracy of the substrate.

Furthermore, with the structure described in JP 2001-183573A, since a plate spring is employed, the force with which the mirror is pressed cannot be adjusted. For this reason, when the elasticity of the plate spring is weak, there is a possibility that the mirror will come loose, and when the elasticity of the plate spring is strong, a strong force is required to insert the plate spring, which is a problem in that operational efficiency is reduced.

Furthermore, in a case where the mirror is adhered using an adhesive, there is a problem in that it becomes difficult to remove the mirror.

### SUMMARY OF THE INVENTION

The present invention has been devised to address the above-mentioned problems, and it is an object thereof to provide a substrate fastening structure that is capable of reliably securing a substrate to a casing using a simple structure, and that is capable of improving the mounting position accuracy of the substrate.

Furthermore, an object of the present invention is to provide an optical scanning device capable of detecting light with excellent accuracy by providing a substrate fastening structure in which the mounting position accuracy of the substrate is improved.

Furthermore, an object of the present invention is to provide an image forming apparatus that operates stably by providing an optical scanning device capable of detecting light with excellent accuracy.

A substrate fastening structure according to the present invention is directed to a substrate fastening structure provided with a substrate on which an electronic component is mounted, and a casing to which the substrate is secured internally, wherein the casing includes a reference portion having a reference groove formed in a perpendicular direction with respect to a first surface configured on an inner side of the casing, and an opposing portion having an opposing groove opposing the reference groove and formed in a perpendicular direction with respect to the first surface; the opposing portion includes a pass-through hole that is located on an extension of a straight line on which the reference groove and the opposing groove oppose each other, and that passes through the opposing portion; the substrate is inserted extending across the reference groove and the opposing groove, and has an opposing end face that opposes the opposing portion, and has a cut-out portion formed in the opposing end face; and a fastening member that is inserted into the pass-through hole presses the cut-out portion.

With this configuration, by pressing the cut-out portion of the substrate with the fastening member, the substrate can be reliably secured to the casing using a simple structure, and the mounting position accuracy of the substrate can be improved. Furthermore, by providing the cut-out portion in the substrate, the fastening member latches onto the cut-out portion of the substrate and becomes stronger against loosening of the substrate in the direction perpendicular to the first surface.

In the substrate fastening structure according to the present invention, it is preferable that the cut-out portion is a recessed portion.

In the substrate fastening structure according to the present invention, it is preferable that the substrate is configured as a rectangular shape, a bottom surface of the reference groove is formed perpendicular to the first surface, and a bottom surface of the opposing groove is formed perpendicular to the first surface.

With this configuration, the substrate and the reference portion contact at their faces, and therefore tilting of the substrate can be suppressed.

In the substrate fastening structure according to the present invention, it is preferable that the substrate has a reference end face that opposes the reference portion, that the cut-out portion is configured as a shape provided with a first tilted surface, a distance between the first tilted surface and the first surface decreasing from a side of the reference end face to a side of the opposing end face, and that a leading edge of the fastening member contacts with the first tilted surface at a side of the first surface.

With this configuration, the substrate can be pressed toward the first surface and the substrate is secured by the reference portion and the first surface, thereby further improving the mounting position accuracy of the substrate.

In the substrate fastening structure according to the present invention, it is preferable that the cut-out portion is a recessed portion, that the cut-out portion is configured as a shape further provided with a second tilted surface, a distance between the second tilted surface and the first surface increasing from the side of the reference end face to the side of the opposing end face, and that the leading edge of the fastening member contacts with the second tilted surface at an opposite side to the side of the first surface.

With this configuration, the fastening member can press against the substrate in a direction parallel to the first surface without tilting, and the fastening member contacts with the first tilted surface and the second tilted surface, thereby suppressing movement of the fastening member in the direction perpendicular to the first surface, and therefore positional shifting of the substrate in the perpendicular direction can be prevented.

In the substrate fastening structure according to the present invention, it is preferable that the cut-out portion is a triangular shaped recessed portion.

With this configuration, the cut-out portion can be achieved as a simple shape.

In the substrate fastening structure according to the present invention, it is preferable that the reference portion or the opposing portion is integrally formed with a second surface perpendicular to the first surface.

With this configuration, the strength of the portion which secures the substrate can be increased.

In the substrate fastening structure according to the present invention, it is preferable that the opposing portion is integrally formed with a second surface perpendicular to the first surface and that the pass-through hole is configured as a shape passing through from outside the casing.

With this configuration, the fastening member can be inserted from outside the casing, which simplifies the task of inserting the fastening member.

An optical scanning device according to the present invention is directed to an optical scanning device provided with a substrate fastening structure according to the present invention, including a light source that irradiates a light, and wherein the electronic component is an optical detection sensor that detects the light irradiated from the light source.

With this configuration, by providing a substrate fastening structure in which the mounting position accuracy of the substrate is improved, an optical scanning device can be provided that is capable of detecting light with excellent accuracy.

An image forming apparatus according to the present invention is provided with an optical scanning device according to the present invention.

With this configuration, by providing an optical scanning device that is capable of detecting light with excellent accuracy, an image forming apparatus can be provided in which operation is stable.

### BRIEF DESCRIPTION OF THE DRAWINGS

FIG. 1 is a principal component perspective view showing a portion of a substrate fastening structure according to embodiment 1 of the present invention.

FIG. 2A is a principal component front view that shows a front surface of a substrate as a main part as viewed from an arrow A direction in FIG. 1.

FIG. 2B is a principal component top view that shows a top surface of the substrate as a main part as viewed from an arrow B direction in FIG. 1.

FIG. 2C is a principal component cross-sectional view through arrows C to C in FIG. 2A.

FIG. 3 is an explanatory diagram (front view) showing the substrate and the fastening member of FIG. 2A taken out.

FIG. 4 is a diagram showing a variation 1 of a substrate, and is an explanatory diagram (front view) showing the substrate and the fastening member taken out.

FIG. 5 is a diagram showing a variation 2 of a substrate, and is an explanatory diagram (front view) showing the substrate and the fastening member taken out.

FIG. 6 is a diagram showing a variation 3 of a substrate, and is an explanatory diagram (front view) showing the substrate and the fastening member taken out.

FIG. 7 is a diagram showing a variation 4 of a substrate, and is an explanatory diagram (front view) showing the substrate and the fastening member taken out.

FIG. 8 is an outline configuration drawing showing a configuration of an optical scanning device according to embodiment 2 of the present invention.

FIG. 9 is a lateral view showing an outline configuration of an image forming apparatus according to embodiment 3 of the present invention.

### DESCRIPTION OF THE PREFERRED EMBODIMENTS

### Embodiment 1

Hereinafter, description is given of a substrate fastening structure according to embodiment 1 of the present invention with reference to the accompanying drawings.

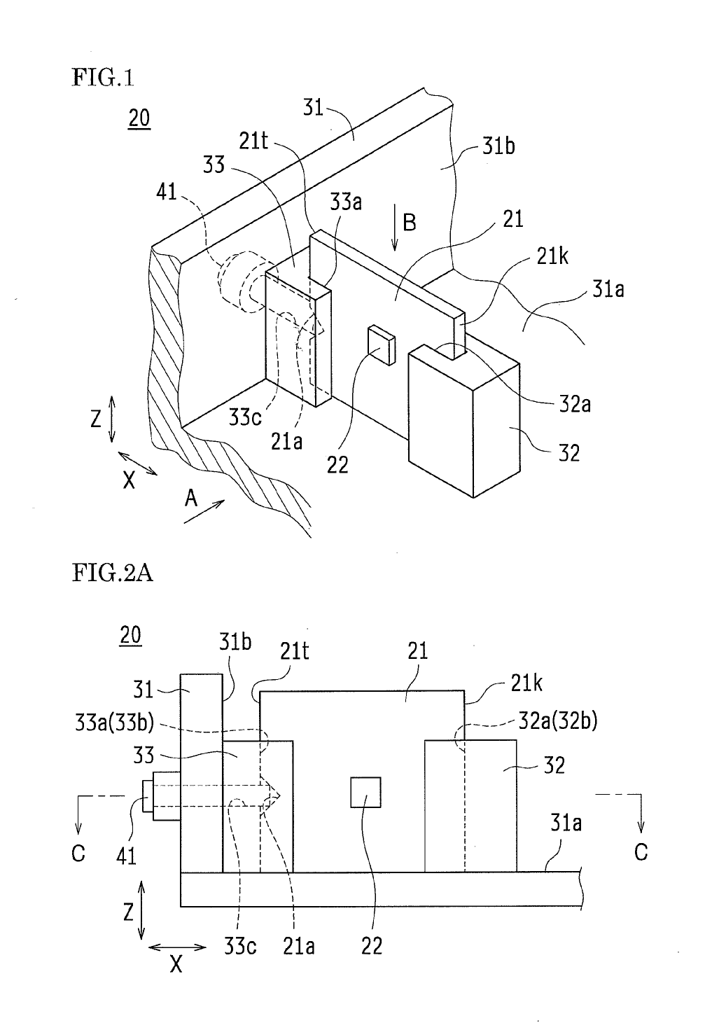

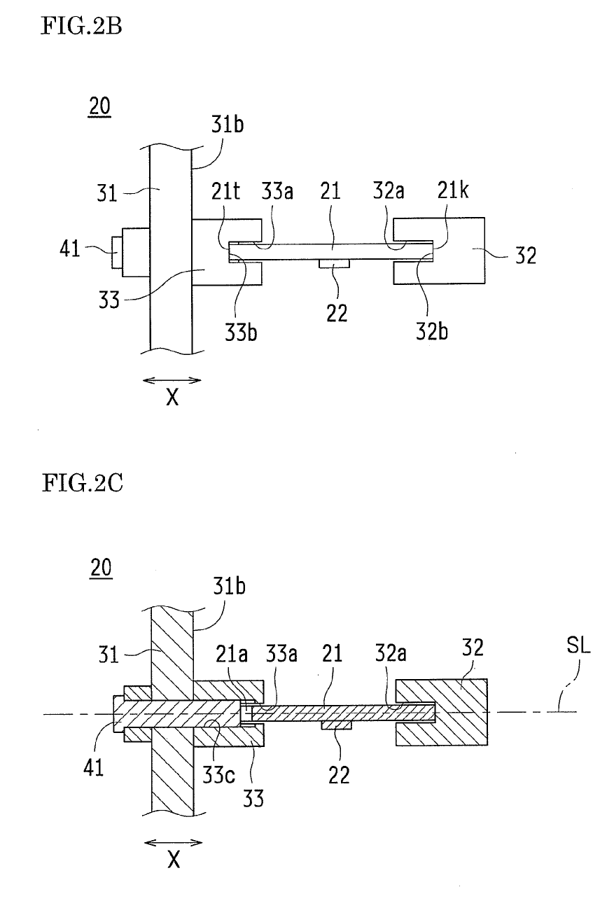

FIG. 1 is a principal component perspective view showing a portion of a substrate fastening structure according to embodiment 1 of the present invention. FIG. 2A is a principal component front view that shows a front surface of a substrate as a main part as viewed from an arrow A direction in FIG. 1. FIG. 2B is a principal component top view that shows a top surface of the substrate as a main part as viewed from an arrow B direction in FIG. 1. FIG. 2C is a principal component cross-sectional view through arrows C to C in FIG. 2A.

A substrate fastening structure 20 according to embodiment 1 of the present invention is provided with a substrate 21, in which an electronic component (for example, an optical detection sensor 22) is mounted, and a casing 31, to which the substrate 21 is secured internally. The casing 31 is provided with a reference portion 32 having a reference groove 32a that is formed in a perpendicular direction Z with respect to a first surface 31a configured inside the casing 31, and an opposing portion 33 having an opposing groove 33a that opposes the reference groove 32a and is formed in the perpendicular direction Z with respect to the first surface 31a. The opposing portion 33 is provided with a pass-through hole 33c that is located on an extension of a straight line SL on which the reference groove 32a and the opposing groove 33a oppose each other (on a straight line joining a point on the reference groove 32a and a point on the opposing groove 33a) and that passes through the opposing portion 33. The substrate 21 is inserted extending across the reference groove 32a and the opposing groove 33a. The substrate 21 has an opposing end face 21t that opposes the opposing portion 33. The substrate 21 has a recessed portion 21a as a cut-out portion formed in the opposing end face 21t. A fastening member 41, which is inserted into the pass-through hole 33c, presses the recessed portion 21a. It should be noted that hereinafter, for the purpose of description, the direction in which the reference groove 32a and the opposing groove 33a oppose each other, and which is a direction parallel to the first surface 31a, is referred to as a fastening direction X.

With this configuration, by pressing the recessed portion 21a of the substrate 21 with the fastening member 41, the substrate 21 can be secured reliably to the casing 31 using a simple structure, and the mounting position accuracy of the substrate 21 can be improved. Furthermore, by providing the recessed portion 21a in the substrate 21, the fastening member 41 latches onto the recessed portion 21a of the substrate 21, which is stronger against loosening of the substrate 21 in the perpendicular direction Z.

In the present embodiment, the substrate 21 is rectangular, a bottom surface 32b of the reference groove 32a is formed perpendicular to the first surface 31a, and a bottom surface 33b of the opposing groove 33a is formed perpendicular to the first surface 31a. With this configuration, the substrate 21 and the reference portion 32 contact at their faces, and therefore tilting of the substrate 21 can be suppressed. It should be noted that the present invention is not limited to this, and when the substrate 21 is another shape, the reference groove 32a and the opposing groove 33a may be formed along the fastening direction X, and the bottom surface 32b of the reference groove 32a and the bottom surface 33b of the opposing groove 33a may be tilted in the fastening direction X with respect to the first surface 31a in accordance with the shape of the substrate 21.

In the present embodiment, the opposing portion 33 is integrally formed with a second surface 31b perpendicular to the first surface 31a, and the pass-through hole 33c is shaped so as to pass through the casing 31 and the opposing portion 33 from outside the casing 31. With this configuration, the fastening member 41 can be inserted from outside the casing 31, which simplifies the task of inserting the fastening member 41. Furthermore, in a case where the fastening member 41 is a screw provided with a Phillips or slotted hole on the top surface of its head, the aforementioned screw can be fastened easily using a driver (screwdriver) from outside the casing 31.

It should be noted that the present invention is not limited to this, and the reference portion 32 may be integrally formed with the second surface 31b. With this configuration, the strength of the portion that secures the substrate 21 can be increased. Here, the pass-through hole 33c may be shaped so as to pass through the opposing portion 33 from outside the casing 31. The pass-through hole 33c is formed facing the opposing groove 33a from a surface opposite to a surface that opposes the reference portion 32.

The casing 31 is formed by molding a synthetic resin in a metal mold. The reference portion 32 and the opposing portion 33 are integrally formed with the first surface 31a.

The substrate 21 inserts perpendicularly into the reference portion 32 and the opposing portion 33 with respect to the first surface 31a of the casing 31. The interval between the reference portion 32 and the opposing portion 33 is decided in accordance with the size of the substrate 21, and the interval between the bottom surface 32b of the reference groove 32a and the bottom surface 33b of the opposing groove 33a is substantially equivalent to the width of the substrate 21 (the interval from a reference end face 21k to the opposing end face 21t). It should be noted that the substrate 21 is pushed against the reference portion 32 by the fastening member 41, and therefore even if there is a gap between the opposing end face 21t and the bottom surface 33b of the opposing groove 33a, the position of the substrate 21 does not shift.

In the present embodiment, the fastening member 41 is a screw. It is preferable that the fastening member 41 is a screw provided with a Phillips or slotted hole on the top surface of its head. It should be noted that the fastening member 41 is not limited to this and, for example, may be achieved using a rivet. The diameter of the fastening member 41 is larger than the thickness of the substrate 21 and smaller than the length in the perpendicular direction Z of the recessed portion 21a. Due to this, the fastening member 41 fits into the recessed portion 21a and can reliably press the substrate 21.

The pass-through hole 33c is shape in accordance with the fastening member 41, and is configured as a cylindrical shape having a same diameter (inner diameter) as a diameter (outer diameter) of the fastening member 41. In the present embodiment, the pass-through hole 33c is shaped having a spiral groove corresponding to a spiral groove of the fastening member 41.

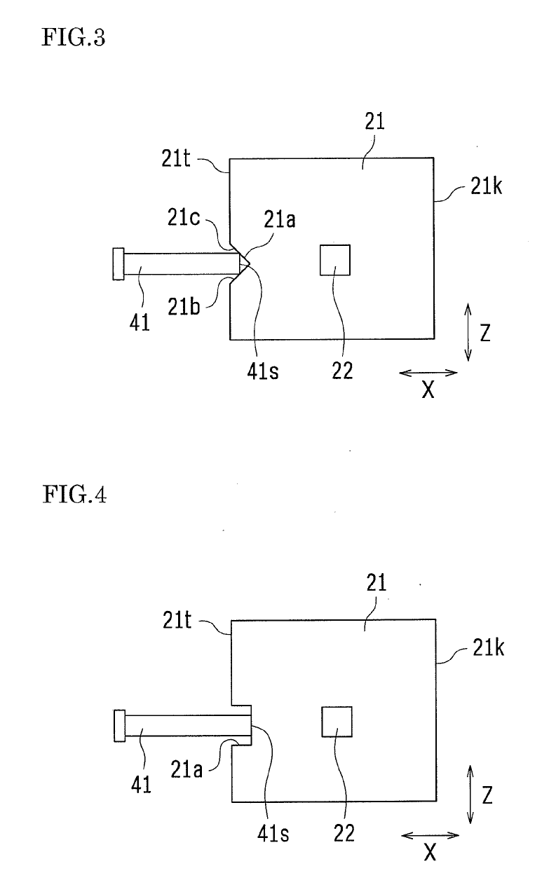

FIG. 3 is an explanatory diagram (front view) showing the substrate and the fastening member of FIG. 2A taken out.

The substrate 21 has the reference end face 21k that opposes the reference portion 32. The recessed portion 21a is formed having a flat tilted surface (first tilted surface) 21b. The distance between the tilted surface 21b and the first surface 31a decreases from the reference end face 21k side that opposes the reference portion 32 to the opposing end face 21t side. A first surface 31a side of a leading edge 41s of the fastening member 41 contacts with the tilted surface 21b. With this configuration, the substrate 21 can be pushed toward the first surface 31a, and by securing the substrate 21 using the reference portion 32 and the first surface 31a, the mounting position accuracy of the substrate 21 can be further improved. It should be noted that the above-mentioned leading edge 41s of the fastening member 41 indicates a side of the screw tip (side opposite to the bearing surface). Furthermore, hereinafter, for the purpose of description, the leading edge 41s of the fastening member 41 closer to the first surface 31a side may be referred to as a leading edge lower side, and the leading edge 41s on the side opposite to the leading edge lower side may be referred to as a leading edge upper side.

In the present embodiment, the recessed portion 21a is a triangular shape. With this configuration, the recessed portion 21a can be achieved as a simple shape.

The recessed portion 21a is formed having a flat tilted surface (second tilted surface) 21c. The distance between the tilted surface 21c and the first surface 31a increases from the reference end face 21k side that opposes the reference portion 32 to the opposing end face 21t side. An opposite side (upper side) to the first surface 31a side of the leading edge 41s of the fastening member 41 contacts with the tilted surface 21c. Accordingly, the leading edge upper side and the leading edge lower side of the fastening member 41 contact with the recessed portion 21a. Due to this, the fastening member 41 can press the substrate 21 in the fastening direction X without tilting, and therefore it is possible to prevent positional shifting of the substrate 21 with respect to the perpendicular direction Z when fastening. Furthermore, since the fastening member 41 contacts with the tilted surfaces 21b and 21c, movement of the fastening member 41 in the perpendicular direction Z can be suppressed, and therefore it is possible to prevent positional shifting of the substrate 21 in the perpendicular direction Z after fastening as well.

It should be noted that the substrate fastening structure according to the present invention is not limited to this, and the recessed portion 21a may be achieved as a recessed portion of another shape or as a cut-out portion other than a recessed portion. Description is given regarding variations 1 to 4 of the substrate 21 using FIG. 4 to FIG. 7.

FIG. 4 is a diagram showing a variation 1 of a substrate, and is an explanatory diagram (front view) showing the substrate and the fastening member taken out.

In the variation 1, the cut-out portion is a rectangular recessed portion 21a, and the leading edge of the fastening member 41 and the recessed portion 21a contact at their faces. More specifically, both the leading edge surface of the fastening member 41 and the bottom surface of the recessed portion 21a are flat surfaces parallel to the second surface 31b, and the entire flat surface of the leading edge of the fastening member 41 contacts with the flat surface of the bottom of the recessed portion 21a. This enables tilting of the substrate 21 to be suppressed. It is preferable that a difference between the diameter of the fastening member 41 and a length in the perpendicular direction Z of the recessed portion 21a is within a range of 1 to 3 mm, for example 2 mm. This enables positional shifting of the substrate 21 in the perpendicular direction Z to be prevented.

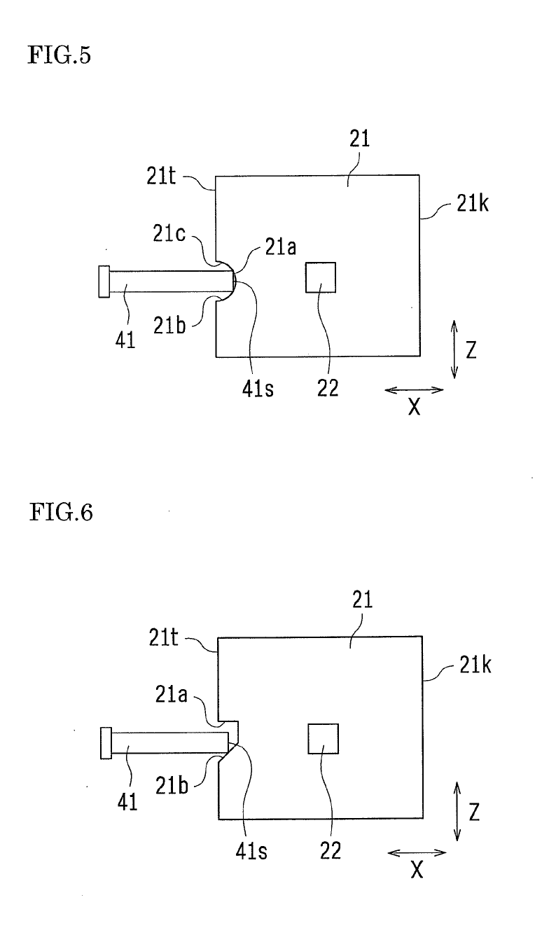

FIG. 5 is a diagram showing a variation 2 of a substrate, and is an explanatory diagram (front view) showing the substrate and the fastening member taken out.

In the variation 2, the cut-out portion is a semicircular recessed portion 21a, and the leading edge upper side and leading edge lower side of the fastening member 41 contact with the recessed portion 21a. That is, the recessed portion 21a is formed having an arc-shaped tilted surface 21b and an arc-shaped tilted surface 21c, the distance between the tilted surface 21b and the first surface 31a decreases from the reference end face 21k side that opposes the reference portion 32 to the opposing end face 21t side, the distance between the tilted surface 21c and the first surface 31a increases from the reference end face 21k side that opposes the reference portion 32 to the opposing end face 21t side, and the first surface 31a side of the leading edge 41s of the fastening member 41 contacts with the tilted surface 21b, and the side opposite to the first surface 31a side contacts with the tilted surface 21c. Due to this, the fastening member 41 can press the substrate 21 in the fastening direction X without tilting, and therefore it is possible to prevent positional shifting of the substrate 21 with respect to the perpendicular direction Z when fastening. Furthermore, the fastening member 41 contacts with the tilted surface 21b and the tilted surface 21c, thereby suppressing movement of the fastening member 41 in the perpendicular direction Z, and therefore it is possible to prevent positional shifting of the substrate 21 in the perpendicular direction Z after fastening as well. It should be noted that the present invention is not limited to this and, for example, if the tilted surface 21b, which is configured as an arc shape, is formed at the area of the recessed portion 21a contacting with the leading edge lower side, then the leading edge upper side of the fastening member 41 does not have to contact with the recessed portion 21a.

FIG. 6 is a diagram showing a variation 3 of a substrate, and is an explanatory diagram (front view) showing the substrate and the fastening member taken out.

In the variation 3, the cut-out portion is a trapezoidal shaped recessed portion 21a, and the tilted surface 21b is formed at an area of the recessed portion 21a that contacts with the leading edge lower side. That is, the recessed portion 21a is formed having a flat surface shaped tilted surface 21b, the distance between the tilted surface 21b and the first surface 31a decreases from the reference end face 21k side that opposes the reference portion 32 to the opposing end face 21t side, and the first surface 31a side of the leading edge 41s of the fastening member 41 contacts with the tilted surface 21b. The leading edge upper side of the fastening member 41 does not contact with the recessed portion 21a.

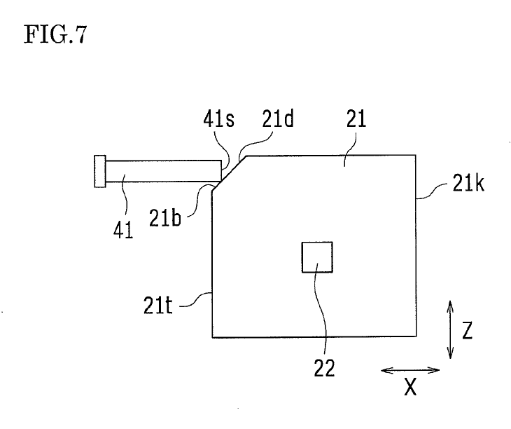

FIG. 7 is a diagram showing a variation 4 of a substrate, and is an explanatory diagram (front view) showing the substrate and the fastening member taken out.

In the variation 4, the cut-out portion is a cut-out portion 21d formed at an upper edge corner (an end face side opposite to the end face opposing the first surface 31a) of the substrate 21. That is, in the variation 4, the substrate 21 is shaped such that the cut-out portion 21d is formed by cutting out a corner portion of the opposing end face 21t of the rectangular substrate at an opposite side (upper side) to the first surface 31a side. The cut-out portion 21d is formed having a flat surface shaped tilted surface 21b, and the distance between the tilted surface 21b and the first surface 31a decreases from the reference end face 21k side that opposes the reference portion 32 to the opposing end face 21t side. The leading edge lower side of the fastening member 41 contacts with the cut-out portion 21d. That is, the first surface 31a side of the leading edge 41s of the fastening member 41 contacts with the tilted surface 21b.

### Embodiment 2

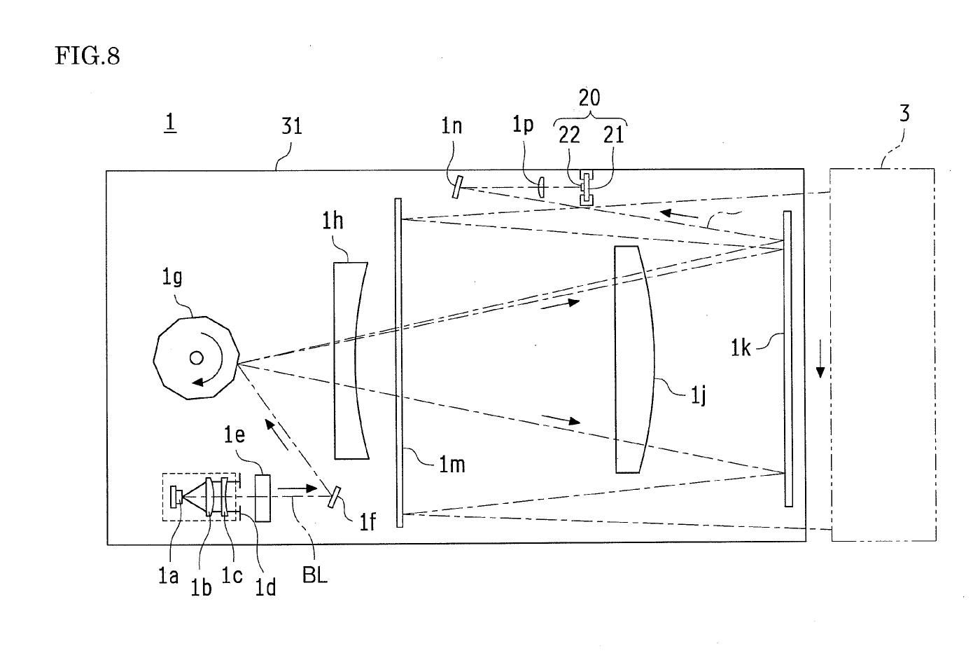

FIG. 8 is an outline configuration drawing showing a configuration of an optical scanning device according to embodiment 2 of the present invention. It should be noted that same symbols are assigned and description is omitted in regard to configuration elements whose function and structure are essentially equivalent to those of embodiment 1.

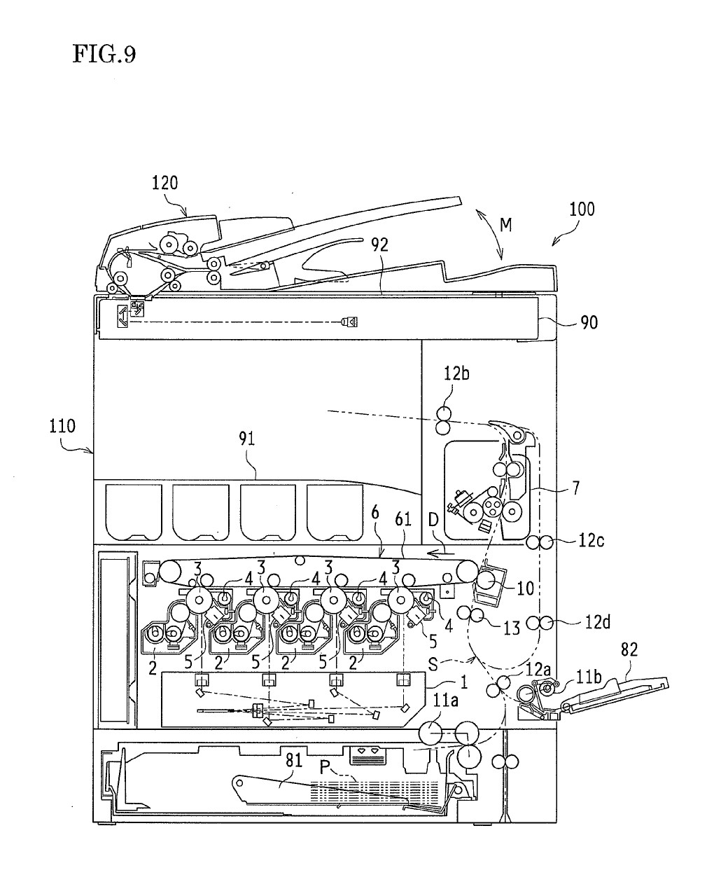

In an optical scanning device 1 according to embodiment 2 of the present invention, a light source 1a, a collimator 1b, a concave lens 1c, an aperture 1d, a cylindrical lens 1e, an incident turning mirror 1f, a light polarizer 1g, a first scanning lens 1h, a second scanning lens 1j, an outgoing turning mirror 1k, and a cylindrical mirror 1m are arranged in order from upstream to downstream in the direction of advancement of a light BL irradiated from the light source 1a. It should be noted that the present invention is not limited to this and, for example, the order in which the second scanning lens 1j, the outgoing turning mirror 1k, and the cylindrical mirror 1m are arranged may be switched as appropriate in response to the direction in which light from the optical scanning device 1 is irradiated. The light BL reflected by the cylindrical mirror 1m is launched from the optical scanning device 1 and irradiates a surface of a photosensitive drum 3 of an image forming apparatus 100 (see FIG. 9) that is described later.

The light source 1a is a laser diode or the like for example. A cross section (beam cross section) perpendicular to the optical axis of the light BL irradiated from the light source 1a is set as a circular shape. The collimator 1b is an optical component that shapes the conical light BL that is output in a diffuse manner from the light source 1a into a parallel shaped light BL. The concave lens 1c is an optical component that converges the light BL shaped by the collimator 1b. The aperture 1d is a panel shaped member in which a rectangular opening has been formed. The aperture 1d is an optical component that shapes the beam cross section when the light BL passes through from an elliptical shape to a rectangular shape. The cylindrical lens 1e and the incident turning mirror 1f are optical components for converging the light BL onto reflective surfaces of the light polarizer 1g.

The light polarizer 1g is a polygon mirror on which multiple reflective surfaces are formed, and is rotationally driven by an unshown driver. When the light polarizer 1g is rotationally driven, a spot of light BL moves in a scanning direction on the surface of the photosensitive drum 3, thereby scanning the photosensitive drum 3. Hereinafter, a range of the photosensitive drum 3 which is scanned by the light BL in the scanning direction is referred to as a scanning range.

The first scanning lens 1h and the second scanning lens 1j are optical components for correcting image distortion that is produced originating in a disparity between an optical path length of the light BL irradiated at edge portions of the scanning range and an optical path length of the light BL irradiated at a center of the scanning range. That is, the first scanning lens 1h and the second scanning lens 1j are optical components that cause the light BL scanned by the light polarizer 1g to scan at a constant velocity on the photosensitive drum 3, and may also be referred to as an f-theta lens.

The outgoing turning mirror 1k and the cylindrical mirror 1m are light reflecting members that reflect the irradiated light BL and guide it to the photosensitive drum 3.

Furthermore, the optical scanning device 1 is further provided with a reflective mirror in, a converging lens 1p, and an optical detection sensor 22 (beam detector: BD sensor).

The reflective mirror 1n reflects the light BL irradiated from the light polarizer 1g to the edge portions of the scanning range and guides it to the optical detection sensor 22. The converging lens 1p converges the light BL reflected by the reflective mirror 1n and causes it to be irradiated on the optical detection sensor 22.

The optical detection sensor 22 receives the light BL and detects timings of a scan commencement or a scan completion for each line on the photosensitive drum 3, and outputs results thereof as signals. The optical detection sensor 22 is mounted on the above-described substrate 21, and the substrate 21 is secured to the casing 31.

The optical system of the optical scanning device 1 requires high positional accuracy since malfunctions or the like are produced by slight positional shifts. The same is true of the optical detection sensor 22 and the timings of the scan commencement or scan completion shift when the position of the optical detection sensor 22 shifts such that shifts are produced in the printing position in an image forming apparatus 100 that is described later.

As described above, the optical scanning device 1 is provided with the light source 1a that irradiates the light BL, and an electronic component mounted on the substrate 21 is the optical detection sensor 22 that detects the light BL irradiated from the light source 1a. With this configuration, by providing the substrate fastening structure 20 in which positional accuracy is improved, it is possible to provide the optical scanning device 1 that is capable of detecting light with excellent accuracy.

In the casing 31, the light source 1a, the collimator 1b, the concave lens 1c, the aperture 1d, the cylindrical lens 1e, the incident turning mirror 1f, the light polarizer 1g, the first scanning lens 1h, the second scanning lens 1j, the outgoing turning mirror 1k, the cylindrical mirror 1m, the reflective mirror 1n, and the converging lens 1p are arranged as appropriate and secured to the casing 31. Furthermore, an unshown opening is formed in the casing 31, and the light BL that is launched from the opening is irradiated onto the photosensitive drum 3.

It should be noted that the optical scanning device 1 according to the present invention is not limited to this and, for example, a configuration is possible in which multiple light sources 1a are provided. Furthermore, a structure is also possible in which multiple second scanning lenses 1j and outgoing turning mirrors 1k are arranged such that light is launched from multiple locations. In this way, it is possible to configure an optical scanning device 1 in which multiple photosensitive drums 3 are scanned respectively.

### Embodiment 3

FIG. 9 is a lateral view showing an outline configuration of an image forming apparatus according to embodiment 3 of the present invention. It should be noted that same symbols are assigned and description is omitted in regard to configuration elements whose function and structure are essentially equivalent to those of embodiment 1 and embodiment 2.

An image forming apparatus 100 according to embodiment 3 of the present invention is provided with an apparatus main unit 110 and an automatic document processing device 120, and forms a multicolor or single color image on a predetermined paper (original) in response to image data transmitted from outside.

The apparatus main unit 110 is devised as a configuration provided with an optical scanning device 1, development devices 2, photosensitive drums 3, cleaning units 4, chargers 5, an intermediate transfer belt unit 6, and a fixing unit 7.

In addition to the above-mentioned configuration, the image forming apparatus 100 is provided with an original reading device 90 that reads an image of an original, and an original placement platform 92 on which an original is placed. The original reading device 90 is provided at an upper portion of the apparatus main unit 110. The original placement platform 92 is formed using a transparent glass and is provided on an upper side of the original reading device 90.

The automatic document processing device 120 is installed on an upper side of the original placement platform 92, and automatically transports originals onto the original placement platform 92. Furthermore, the automatic document processing device 120 is configured to readily rotate in a direction of arrow M such that an original can be placed manually by opening the top of the original placement platform 92.

The image data processed in the image forming apparatus corresponds to color image data using each of the colors black (K), cyan (C), magenta (M), and yellow (Y). Accordingly, four each of the development devices 2, the photosensitive drums 3, the chargers 5, and the cleaning units 4 are provided corresponding to each of the colors so as to form four types of latent images, which are set to black, cyan, magenta, and yellow respectively. Four image stations are configured by these four sets of the development devices 2, the photosensitive drums 3, the chargers 5, and the cleaning units 4.

The chargers 5 are charging means for uniformly charging the surface of each of the photosensitive drums 3 to a predetermined electric potential, and instead of the corona charger type shown in FIG. 9 it is possible to use contact type chargers (for example, a roller type or a brush type).

The optical scanning device 1 has a function of exposing the surfaces of the charged photosensitive drums 3 in response to inputted image data, and forming electrostatic latent images corresponding to the image data on the surfaces of the photosensitive drums 3.

As described above, the image forming apparatus 100 is provided with the optical scanning device 1. With this configuration, by providing the optical scanning device 1 that is capable of detecting light with excellent accuracy, it is possible to provide the image forming apparatus 100 that operates stably.

A laser scanning unit (LSU) provided with a laser output unit and reflective mirrors and the like, or a writing device (for example, a writing head) in which light emitting elements such as ELs or LEDs are arranged in an array manner can be used as the optical scanning device 1.

The development devices 2 use toners of the four colors (YMCK) to visialize the electrostatic latent images formed on the photosensitive drums 3 respectively.

The cleaner units 4 remove and collect the residual toner on the surfaces of the photosensitive drums 3 after development and image transfer.

The intermediate transfer belt unit 6 is arranged on an upper side of the photosensitive drums 3 and is provided with an intermediate transfer belt 61. The intermediate transfer belt unit 6 is configured such that the surface of the intermediate transfer belt 61 is caused to move in a predetermined direction (arrow D direction in FIG. 9).

The intermediate transfer belt 61 is arranged so as to contact with each of the photosensitive drums 3 and has a function of forming a color toner image (multicolor toner image) on the intermediate transfer belt 61 by sequentially transferring and layering the toner image of each color formed on the photosensitive drums 3 onto the intermediate transfer belt 61.

As described above, the toner images that have been visialized by the color toners on the photosensitive drums 3 are superimposed onto the intermediate transfer belt 61 due to a transfer bias. The superimposed color toner images are moved due to rotation of the intermediate transfer belt 61 then transferred onto a paper by a transfer roller 10, which is arranged at a contact position of the paper and the intermediate transfer belt 61 and to which a transfer voltage has been applied.

The image forming apparatus 100 is further provided with a paper feeding cassette 81, a manual paper feeding cassette 82, and a stacking tray 91. The paper feeding cassette 81 is a tray for accommodating papers P to be used in image forming, and is provided at a lower side of the optical scanning device 1. Furthermore, paper to be used in image forming can also be placed in the manual paper feeding cassette 82. The stacking tray 91 is a tray for stacking the papers P on which images have been formed, and is provided in the apparatus main unit 110.

A substantially vertically shaped paper transport path S is provided in the apparatus main unit 110 for sending the papers in the paper feeding cassette 81 and the manual paper feeding cassette 82 to the stacking tray 91 via the transport roller 10 and the fixing unit 7. Pickup rollers 11a and 11b, multiple transport rollers 12a to 12d, registration rollers 13, the transfer roller 10, and the fixing unit 7 are arranged in the vicinity of the paper transport path S from the paper feeding cassette 81 and the manual paper feeding cassette 82 to the stacking tray 91.

The transport rollers 12a to 12d are small sized rollers for facilitating and assisting the transport of the papers and multiple of these are arranged along the paper transport path S.

The pickup rollers 11a and 11b are provided in the vicinity of edge portions of the paper feeding cassette 81 and the manual paper feeding cassette 82, and is a draw-in roller that supplies papers sheet by sheet from the paper feeding cassette 81 to the paper transport path S.

The registration rollers 13 temporarily hold the paper that is being transported on the paper transport path S and transport the paper to the transfer roller 10 with a timing by which the leading edge of the toner image on the intermediate transfer belt 61 and the leading edge of the sheet are matched.

The fixing unit 7 has a function of melting, mixing, and applying pressure to the multicolor toner image that has been transferred onto the sheet, thereby thermally fixing the image to the sheet.

In performing image forming in the above-described image forming apparatus 100, the papers transported from the paper feeding cassette 81 and the manual paper feeding cassette 82 are transported to the registration rollers 13 by the transport rollers 12a. Next, the paper is transported by the registration rollers 13 to the transfer roller 10 synchronized with the toner image on the intermediate transfer belt 61 such that the toner image is transferred onto the paper by the transfer roller 10. After this, when the paper passes through the fixing unit 7, the unfixed toner that has been transferred onto the paper is melted and bonded by heat, thereby becoming fixed onto the paper. The paper on which the toner image has been fixed is discharged from a paper discharge outlet via the transport rollers 12b to be stacked in the stacking tray 91.

The present invention can be embodied and practiced in other different forms without departing from the spirit and essential characteristics thereof. Therefore, the above-described working examples are considered in all respects as illustrative and not restrictive. The scope of the invention is indicated by the appended claims rather than by the foregoing description. All variations and modifications falling within the equivalency range of the appended claims are intended to be embraced therein.

What is claimed is:

1. A substrate fastening structure comprising a substrate on which an electronic component is mounted, and a casing to which the substrate is secured internally,
wherein the casing comprises:
a reference portion having a reference groove formed in a perpendicular direction with respect to a first surface configured on an inner side of the casing; and
an opposing portion having an opposing groove opposing the reference groove and formed in a perpendicular direction with respect to the first surface;
the opposing portion comprises a pass-through hole that is located on an extension of a straight line on which the reference groove and the opposing groove oppose each other, and that passes through the opposing portion,
the substrate is inserted extending across the reference groove and the opposing groove, and has an opposing end face that opposes the opposing portion, and has a cut-out portion formed in the opposing end face, and
a fastening member that is inserted into the pass-through hole presses the cut-out portion.

2. The substrate fastening structure according to claim 1,
wherein the cut-out portion is a recessed portion.

3. The substrate fastening structure according to claim 1,
wherein the substrate is configured as a rectangular shape,
a bottom surface of the reference groove is formed perpendicular to the first surface, and
a bottom surface of the opposing groove is formed perpendicular to the first surface.

4. The substrate fastening structure according to claim 1,
wherein the substrate has a reference end face that opposes the reference portion,
the cut-out portion is configured as a shape provided with a first tilted surface, a distance between the first tilted surface and the first surface decreasing from a side of the reference end face to a side of the opposing end face, and
a leading edge of the fastening member contacts with the first tilted surface at a side of the first surface.

5. The substrate fastening structure according to claim 4,
wherein the cut-out portion is a recessed portion,
the cut-out portion is configured as a shape further provided with a second tilted surface, a distance between the second tilted surface and the first surface increasing from the side of the reference end face to the side of the opposing end face, and
the leading edge of the fastening member contacts with the second tilted surface at an opposite side to the side of the first surface.

6. The substrate fastening structure according to claim 4,
wherein the cut-out portion is a triangular shaped recessed portion.

7. The substrate fastening structure according to claim 1,
wherein the opposing portion is integrally formed with a second surface perpendicular to the first surface, and
the pass-through hole is configured as a shape passing through from outside the casing.

8. An optical scanning device provided with the substrate fastening structure according to claim 1, comprising:
a light source that irradiates a light,
wherein the electronic component is an optical detection sensor that detects the light irradiated from the light source.

9. An image forming apparatus comprising the optical scanning device according to claim 8.
